(19) United States
(12) Patent Application Publication
(10) Pub. No.: US 2026/0198117 A1
(43) Pub. Date: Jul. 9, 2026

(54) IMAGE SENSING DEVICE AND IMAGING DEVICE INCLUDING THE SAME

(71) Applicant: SK hynix Inc., Icheon-si (KR)

(72) Inventor: Han Seung LEE, Icheon-si (KR)

(21) Appl. No.: 19/239,760

(22) Filed: Jun. 16, 2025

(30) Foreign Application Priority Data
Jan. 6, 2025 (KR) 10-2025-0001523

(51) Int. Cl. H10F 39/00

(52) U.S. Cl. CPC H10F 39/805; H10F 39/807

(57) ABSTRACT

An image sensing device is provided to comprise: a substrate; a pixel region supported by the substrate and configured to detect incident light from a target object to generate pixel data; a non-pixel region disposed on a side of the pixel region; insulation material disposed on a side surface and an upper surface of the substrate; a grid structure disposed on a side surface of the insulation material; and a light receiving pattern disposed on the insulation material and configured to collect the incident light from the target object and to direct the incident light into the pixel region to be detected, wherein a thickness of the insulation material on the upper surface of the substrate is greater than a thickness of the insulation material on the side surface of the substrate.

### PRIORITY AND CROSS REFERENCE TO RELATED APPLICATION

The present application claims priority to Korea Patent Application No. 10-2025-0001523, filed Jan. 6, 2025, the entire contents of which is incorporated herein for all purposes by this reference.

### TECHNICAL FIELD

Implementations of the disclosed technology relate to an image sensing device and an imaging system including the same.

### BACKGROUND

A recently spotlighted time of flight (TOF) technology may include irradiating a light having a pulse shape to an object from a light source in or around a sensor, receiving a reflected light to measure a time between the object and the light source, and extracting a distance between the object and the light source based on a principle of constancy of light velocity. In order to accurately measure the TOF, a reaction needs to be generated as soon as the light is received by a light-receiving element. Thus, a photoelectric conversion element having a high sensitivity is desired. To this end, a single photo avalanche diode (SPAD) manufactured by a CMOS process technology has been widely studied and developed.

### SUMMARY

Some implementations of the disclosed technology provide an image sensing device capable of increasing light transmittance by reducing a reflectance of an upper portion of the SPAD.

Some implementations of the disclosed technology provide an image sensing device capable of improving light reflectance by increasing a reflectance of a side surface of the SPAD.

One embodiment is an image sensing device, including: a substrate; a pixel region supported by the substrate and configured to detect incident light from a target object to generate pixel data; a non-pixel region disposed on a side of the pixel region; insulation material disposed on a side surface and an upper surface of the substrate; a grid structure disposed on a side surface of the insulation material; and a light receiving pattern disposed on the insulation material and configured to collect the incident light from the target object and to direct the incident light into the pixel region to be detected, wherein a thickness of the insulation material on the upper surface of the substrate is greater than a thickness of the insulation material on the side surface of the substrate.

Another embodiment is an image sensing device, including: a substrate including a pixel region and a non-pixel region around the pixel region, and a hole recessing in the non-pixel region, the pixel region including a photoelectric conversion element configured to generate pixel data in response to a detection of light from a target object and the non-pixel region configured without including the photoelectric conversion element; a first insulation layer on an upper surface of the substrate; a second insulation layer on the first insulation layer; a grid structure on a side surface of the second insulation layer; and a light receiving pattern on the second insulation layer, wherein the second insulation layer is in direct contact with a side surface of the substrate.

Still another embodiment is an image sensing device, including a substrate including a pixel region, a non-pixel region around the pixel region, and a hole recessing the substrate in the non-pixel region; a first insulation layer on an upper surface of the substrate; a second insulation layer on the first insulation layer; and a third insulation layer between the first insulation layer and the second insulation layer, wherein a refractive index of the first insulation layer has a value between a refractive index of the second insulation layer and a refractive index of the substrate, and wherein a refractive index of the second insulation layer is lower than or equal to a refractive index of the third insulation layer.

Other details of the embodiments are included in the detailed description and the accompanying drawings.

According to embodiments, it is possible to increase light transmittance by decreasing a reflectance of an upper portion of the substrate portion because the first insulation layer, the second insulation layer, and the light receiving pattern are sequentially stacked on the substrate portion and a refractive index of the first insulation layer has a value between a refractive index of the second insulation layer and a refractive index of the light receiving pattern.

According to embodiments, it is possible to improve a light reflectance by increasing a reflectance of a side surface of the substrate portion because the first insulation layer is not disposed on the side surface of the substrate portion, and the second insulation layer and the first grid portion are sequentially disposed on the side surface of the substrate portion.

The effects of the present disclosure are not limited to the above-described effects and other effects which are not described herein may be clearly understood by those skilled in the art from the following description of the embodiments of the present disclosure.

### BRIEF DESCRIPTION OF THE DRAWINGS

FIG. 1 is an example of a block diagram illustrating an imaging system based on some implementations of the disclosed technology.

FIG. 2 is an example of a plan view illustrating a pixel array based on some implementations of the disclosed technology.

FIG. 3 is a cross-sectional view taken along A-A′ line in FIG. 2.

FIG. 4 is an enlarged cross-sectional view of Q1 region of FIG. 3.

FIG. 5 is an example of a view for describing a direct ToF method of a pixel.

FIG. 6 is an example of a view for describing an indirect ToF method of a pixel.

FIG. 7 is an example of a view illustrating an imaging system based on some implementations of the disclosed technology.

FIG. 8 is an example of a view illustrating a mode of a single photo avalanche diode based on some implementations of the disclosed technology.

FIG. 9 is a histogram showing pixel data generated by a pixel configured based on some implementations of the disclosed technology.

FIGS. 10 to 14 are cross-sectional views illustrating stages of a method for manufacturing a pixel array based on some implementations of the disclosed technology.

FIG. 15 is a schematic view illustrating light reflection of a pixel array based on some implementations of the disclosed technology.

FIG. 16 is a cross-sectional view illustrating an image sensing device based on some implementations of the disclosed technology.

FIG. 17 is a cross-sectional view illustrating an image sensing device based on some implementations of the disclosed technology.

### DETAILED DESCRIPTION

Example embodiments will now be described more fully with reference to the accompanying drawings.

Like reference numerals refer to like elements throughout. Additionally, in the drawings, the thicknesses, proportions, and dimensions of components may be exaggerated for ease of description and clarity. “And/or” includes all of one or more combinations defined by related components.

In various embodiments of the present disclosure, the terms “include,” “comprise,” “including,” or “comprising,” may refer to a property, a fixed number, a step, a process, a component or combination thereof, but do not exclude other properties, fixed numbers, steps, processes, components or combination thereof.

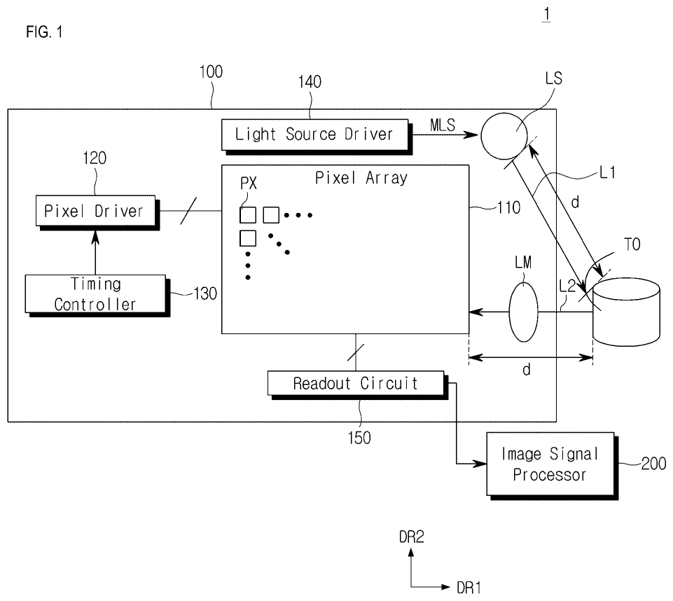

FIG. 1 is a block diagram illustrating an imaging system based on some implementations of the disclosed technology.

Referring to FIG. 1, an imaging system 1 may refer to a device, for example, a digital still camera for photographing still images or a digital video camera for photographing moving images. For example, an imaging device 10 may be implemented as a Digital Single Lens Reflex (DSLR) camera, a mirrorless camera, or a mobile phone (in particular, a smartphone), but is not limited thereto. The imaging system 1 may be a concept of including a device having a lens and an image pickup element such that the device can capture a target object and can thus create an image of the target object.

The imaging system 1 may include an image sensing device 100 and an image signal processor 200.

The image sensing device 100 may measure a distance using a principle of TOF (Time of Flight). The image sensing device 100 may include a light receiving pattern LM, a pixel array 110, a pixel driver 120, a timing controller 130, a light source driver 140, and a readout circuit 150. The imaging system 1 according to an embodiment of the present disclosure may further include a light sensor 300. The imaging system 1 may further include a light source LS.

The light source LS may irradiate light to a target object TO in response to a clock signal, e.g., a modulated light signal (MLS), from the light source driver 140. The modulated light signal MLS may be a signal modulated at a predetermined frequency so that the output light from the light source LS is modulated at this predetermined frequency. The light source LS may be or include a laser diode LD for emitting a light having a specific wavelength such as an infrared light or a visible light, a light irradiating diode (LED), a near infrared laser (NIR), a point light source, a white light lamp, a monochromatic illuminator in which a monochromator is combined, other laser light source LS, or combination thereof. For example, the light source LS may emit an infrared light having a wavelength of 800 nm to 1,000 nm. FIG. 1 shows one light source LS for convenience of description; however, a plurality of light sources LS may be disposed around the light receiving pattern LM. In an embodiment, a VCSEL (Vertical cavity surface irradiating laser) including a point light source has been given as an example of the light source LS, but the embodiment of the present disclosure is not limited thereto.

The light receiving pattern LM may collect light reflected from the target object TO and may focus the light to pixels of the pixel array 110. The light receiving pattern LM may include a focusing lens having a glass or plastic surface, or another optical element. The light receiving pattern LM may include one lens group formed by at least one lens.

The pixel array 110 may include a plurality of pixels PX disposed continuously in a two-dimensional matrix structure. In some implementations, the pixel array 110 may include a plurality of pixels PX disposed continuously along a first direction DR1 and a second direction DR2. Each pixel PX may include a photoelectric conversion element which photoelectrically converts a second light L2 (or an incident light) received through the light receiving pattern LM into an electrical signal as a pixel signal representing the detected second light L2. At this instance, the pixel signal may be a signal indicating information corresponding to a distance to the target object TO, rather than a signal indicating a color with respect to the target object TO. Each of the plurality of pixels may include a single photo avalanche diode for detecting the distance to the target object TO by detecting the modulated light from the light source LS that is reflected from the target object TO and another optical detector to capture the imaging information of the target object.

In some implementations, the pixel array 110 in which the plurality of pixels SP are disposed may detect a distance to the target object TO using the direct ToF method. The direct ToF is a method for calculating a distance to the target object TO by directly measuring a reciprocation time from a time point when the pulse light is irradiated to the target object TO to a time point when the pulse light is reflected from the target object TO and becomes incident, and calculating the reciprocation time and light velocity. However, the embodiments of the present disclosure are not limited thereto, and the pixel array 110 in which the plurality of pixels SP are disposed may detect a distance to the target object TO using an indirect ToF method as well.

The pixel driver 120 may drive the pixel array 110 based on the control of the timing controller 130. For example, the pixel driver 120 may generate a quenching control signal for controlling a quenching operation, which reduces a reverse bias voltage applied to the pixel PX to a breakdown voltage or less. Thus, the pixel driver 120 may control turning on/off of the pixel PX based on the control of the timing controller 130.

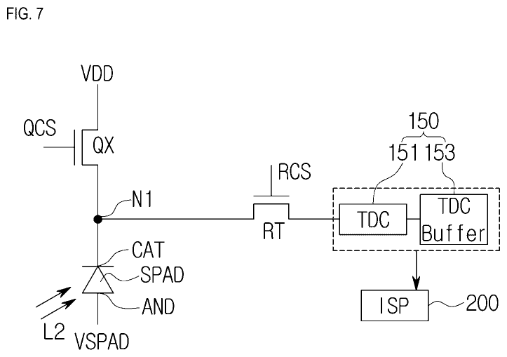

The readout circuit 150 is disposed on one side of the pixel array 110, and may calculate a time delay between a pulse signal (or a pixel signal) output from each pixel PX and a reference pulse, and generate (refer to a TDC (time-to-digital) section 151 of the readout circuit 150 in FIG. 7) digital data (pixel data) corresponding to the time delay, and store (refer to a TDC buffer 153 of the readout circuit 150 in FIG. 7) the digital data. The readout circuit 150 may transmit the stored digital data to the image signal processor 200 according to the control of the timing controller 130.

The timing controller 130 may control the overall operations of the image sensing device 100. That is, the timing controller 130 may generate a timing signal for controlling the operation of the pixel driver 120 and the light source driver 140. In addition, the timing controller 130 may control activation or inactivation of the readout circuit 150, and may control to transmit digital data stored in the readout circuit 150 to the image signal processor 200 simultaneously or sequentially.

The light source driver 140 may generate a clock signal capable of operating the light source LS based on the control of the timing controller 130.

The image signal processor 200 may process digital data (or pixel data) input from the image sensing device 100, and generate a depth image (in the form of a histogram) representing a distance to the target object TO. In more detail, the image signal processor 200 may calculate a distance to the target object TO per pixel based on the time delay represented by the digital data received from the readout circuit 150.

The image signal processor 200 may control operations of the image sensing device 100. In particular, the image signal processor 200 may analyze digital data input from the image sensing device 100 to determine a mode of the image sensing device 100, and may control the image sensing device 100 to operate in the determined mode.

The image signal processor 200 may perform image signal processing for removing noise and improving the image quality with respect to the generated depth image. The depth image output from the image signal processor 200 may be stored in an internal memory or an external memory of the imaging system 1 or a device in which the imaging system 1 is embedded, or may be displayed through the display at the request of the user or automatically. Alternatively, the depth image output from the image signal processor 200 may be used for controlling the operation of the imaging system 1 or the device in which the imaging system 1 is embedded.

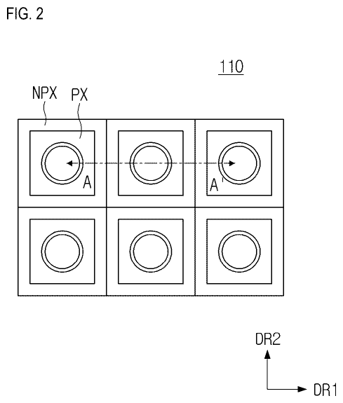

FIG. 2 is a plan view illustrating a pixel array according to an embodiment of the disclosed technology.

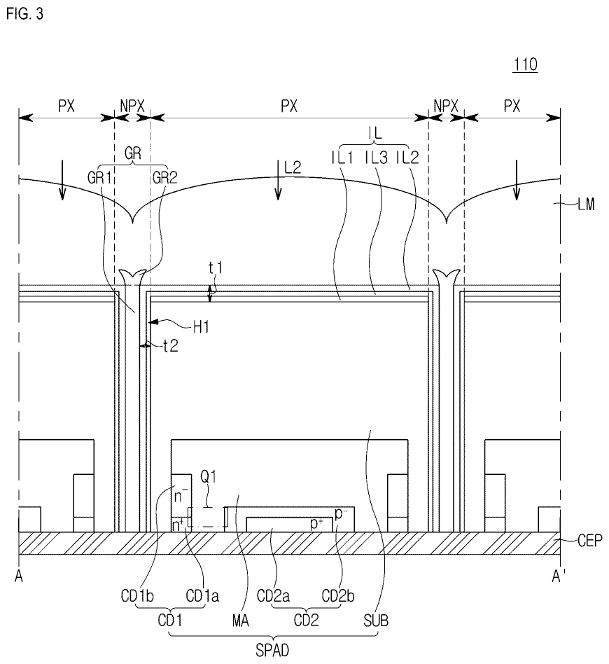

Referring to FIGS. 2 and 3, the pixel array 110 may include the plurality of pixels. Each of the plurality of pixels may include a pixel region PX and a non-pixel region NPX surrounding the pixel region PX. An area of each pixel may be the same, but embodiments of the present disclosure are not limited thereto and the area thereof may differ from one another.

A cross-sectional structure of the pixel will be described with reference to FIG. 3.

FIG. 3 is a cross-sectional view taken along A-A′ line in FIG. 2. In various implementations, such a pixel array is supported by a substrate (SUB) by suitable integrated circuit fabrication processes. FIG. 3 illustrates one example of a pixel of the pixel array 110 and portions of two adjacent pixels.

Referring to FIG. 3, the pixel array 110 according to an embodiment may include, within in each pixel, a circuit portion CEP, a substrate SUB, a photoelectric conversion element which may be a single photo avalanche diode SPAD on the circuit portion CEP, and the light receiving pattern LM on the single photo avalanche diode SPAD, but embodiments of the present disclosure are not limited thereto.

The circuit portion CEP may be disposed as the peripheral circuit area that is disposed below the substrate SUB including the single photo avalanche diode SPAD. The circuit portion CEP may include transistors, a wiring layer, and/or an inter-layer insulating layer. The transistors may include a readout transistor, an analog quenching transistor formed below the single photo avalanche diode SPAD, and/or others. The transistors will be described by referring to FIG. 7 below.

The single photo avalanche diode SPAD may include a first semiconductor region CD1, a second semiconductor region CD2, an intermediate region MA disposed between the first semiconductor region CD1 and the second semiconductor region CD2 and covering the first semiconductor region CD1 and the second semiconductor region CD2, and a substrate portion SUB on the second semiconductor region CD2 and the intermediate region MA.

The first semiconductor region CD1 may be an n-type semiconductor region, and the second semiconductor region CD2 may be a p-type semiconductor region. For example, the p-type ions may include boron (B) ions, and the n-type ions may include phosphorous (P) and/or arsenic (As) ions. For example, the first semiconductor region CD1 may include a 1-1 semiconductor region CD1a which is an n+ type semiconductor region on the circuit portion CEP, and a 1-2 semiconductor region CD1b which is an n-type semiconductor region on the 1 -1 semiconductor region CD1a, and the second semiconductor region CD2 may include a 2-1 semiconductor region CD2a which is an p+ type semiconductor region on the circuit portion CEP, and a 2-2 semiconductor region CD2b which is an p-type semiconductor region on the 2-1 semiconductor region CD2a.

For example, the 1-1 semiconductor region CD1a may have a higher doping concentration of an n-type impurity compared to that of the 1-2 semiconductor region CD1b, and the 2-1 semiconductor region CD2a may have a higher doping concentration of a p-type impurity compared to that of the 2-2 semiconductor region CD2b, however, the embodiments of the present disclosure are not limited thereto, and the first semiconductor region CD1 and the second semiconductor region CD2 may have one n-type semiconductor region and one p-type semiconductor region.

In some embodiments, vertical positions of the 1 -1 semiconductor region CD1 a and the 1-2 semiconductor region CD1b may be changed, and vertical positions of the 2-1semiconductor region CD2a and the 2-2 semiconductor region CD2b may be changed. For example, the 1-1 semiconductor region CD1a and the 2-1 semiconductor region CD2a may be disposed on the 1-2 semiconductor region CD1b and the 2-2 semiconductor region CD2b, respectively.

The intermediate region MA may be disposed between the first semiconductor region CD1 and the second semiconductor region CD2. The intermediate region MA may be disposed on an upper surface of the first semiconductor region CD1 and the second semiconductor region CD2 to cover the first semiconductor region CD1 and the second semiconductor region CD2. The mechanism of electrons (e−) and holes (h+) in the intermediate region MA will be described below.

In FIG. 2, it is illustrated that the second semiconductor region CD2 is disposed at a central area of the single photo avalanche diode SPAD and the first semiconductor region CD1 is disposed in a peripheral area disposed on the side of the central area of the single photo avalanche diode SPAD. However, the embodiments of the present disclosure are not limited thereto, and positions of the first semiconductor region CD1 and the second semiconductor region CD2 may be changed.

The substrate portion SUB may be disposed on the intermediate region MA to cover the intermediate region MA. In some implementations, the substrate portion SUB refers to an area between the circuit portion CEP and the light receiving pattern LM, which supports the single photo avalanche diode SPAD by providing a space for the single photo avalanche diode SPAD. The substrate portion SUB may include an n-type semiconductor region or a p-type semiconductor region. However, the doping concentration of the impurity of the substrate portion SUB may be lower than those of the first semiconductor region CD1 and the second semiconductor region CD2.

A first groove H1 may be formed in the non-pixel region NPX of the substrate portion SUB. Each of the first groove H1 may be indented in a thickness direction in the substrate portion SUB. For example, the first groove H1 may penetrate the substrate portion SUB from an upper surface to a lower surface thereof completely. The first groove H1 may be formed by a deep trench process.

In some embodiments, in the pixel region PX, a second groove H2 may be formed. One or two second grooves H2 may be provided, or three or more second grooves H2 may be provided.

Hereinafter, an upper surface and a side surface of the substrate portion SUB will be defined. The upper surface of the substrate portion SUB may mean a surface positioned in a direction in which the second light L2 is incident, and the side surface of the substrate portion SUB may mean a surface of the substrate portion SUB facing a first hole H1.

A refractive index of the substrate portion SUB may be about 3.0 to 4.0, but the embodiments of the present disclosure are not limited thereto.

On the upper surface and the side surface of the substrate portion SUB, respectively, at least one insulation layer IL may be disposed. For example, on the upper surface of the substrate portion SUB, a first insulation layer IL1, a second insulation layer IL2, and a third insulation layer IL3 between the first insulation layer IL1 and the second insulation layer IL2 may be disposed. On the side surface (or the first hole H1) of the substrate portion SUB, the third insulation layer IL3 and the second insulation layer IL2 may be sequentially disposed.

The first insulation layer IL1 may be directly disposed on the upper surface of the substrate portion SUB. The first insulation layer IL1 may be in direct contact with the upper surface of the substrate portion SUB. A refractive index of the first insulation layer IL1 may have a value between a refractive index of the second insulation layer IL2 and a refractive index of the substrate portion SUB. For example, the refractive index of the first insulation layer IL1 may about 2.2 to 3.1, but the embodiments of the present disclosure are not limited thereto. For example, the first insulation layer IL1 may include hafnium oxide (HfO2), titania (TiO2), zinc sulfide (ZnS), aluminum nitride (AlN), gallium phosphide (GaP), or cadmium telluride (CdTE), but the embodiments of the present disclosure are not limited thereto. The first insulation layer IL1 may not be disposed on the side surface of the substrate portion SUB.

The third insulation layer IL3 may be disposed on the upper surface of the substrate portion SUB, and may be disposed on the first insulation layer IL1. The third insulation layer IL3 may be directly disposed on the first insulation layer IL1. The third insulation layer IL3 may be on the side surface of the substrate portion SUB, and may be in direct contact with the side surface of the substrate portion SUB. A refractive index of the third insulation layer IL3 may be about 1.5, but the embodiments of the present disclosure are not limited thereto. For example, the third insulation layer IL3 may include aluminum oxide (Al2O3), but the embodiments of the present disclosure are not limited thereto.

The second insulation layer IL2 may be disposed on the third insulation layer IL3. On the upper surface of the substrate portion SUB, the second insulation layer IL2 may be directly disposed on the third insulation layer IL3 and in direct contact with the third insulation layer IL3. On the side surface of the substrate portion SUB, the second insulation layer IL2 may be in direct contact with a side surface of the third insulation layer IL3. For example, a refractive index of the second insulation layer IL2 may be about 1.4 to 1.5. For example, the second insulation layer IL2 may include silicon dioxide (SiO2), but the embodiments of the present disclosure are not limited thereto.

In some implementations, the above-described first insulation layer IL1, the second insulation layer IL2, and the third insulation layer IL3 may be disposed in each of the pixel region PX and the non-pixel region NPX.

A grid portion GR may be disposed in the non-pixel region NPX. For example, the grid portion GR may be disposed between the second insulation layers IL2 respectively disposed in the adjacent pixel regions PX. The grid portion GR is configured to reflect the second light L2 incident on a non-pixel area NPX.

For example, the grid portion GR may be sandwiched between the second insulation layer IL2 of the adjacent pixel regions PX. The grid portion GR may be in direct contact with the second insulation layers IL2 respectively disposed in the adjacent pixel regions PX. The grid portion GR may include a first grid portion GR1, and a second grid portion GR2 on the first grid portion GR1. The first grid portion GR1 and the second grid portion GR2 may be integrally formed by being directly connected to each other, and may include the same material. For example, the grid portion GR may include tungsten (W), but embodiments of the present disclosure are not limited thereto. A surface height of the first grid portion GR1 may be the same with a surface height of the second insulation layer IL2, and the second grid portion GR2 may protrude in a more upward direction than a surface of the second insulation layer IL2.

As described above, according to the pixel array 110 based on some implementations of the disclosed technology, a quantity (e.g., a number) of the insulation layers on the upper surface of the substrate portion SUB and a quantity (e.g., a number) of the insulation layers on the side surface of the substrate portion SUB may differ from each other. The first to the third insulation layers IL1 to IL3 may be disposed on the upper surface of the substrate portion SUB, and only the second and the third insulation layers IL2 and IL3 may be disposed on the side surface of the substrate portion SUB. With this configuration, a thickness t1 of the insulation layer IL on the upper surface of the substrate portion SUB may be greater than a thickness t2 of the insulation layer IL on the side surface of the substrate portion SUB.

In some implementations, it is preferable that the insulation layers IL1, IL2 and IL3 on the upper surface of the substrate portion SUB have a low reflectance with respect to the second light L2 so that the second light L2 which has passed through the light receiving pattern LM is not totally reflected and is incident into the single photo avalanche diode (SPAD).

In some embodiments, the grid portion GR may be omitted and poly-silicon may be disposed in a region in which the grid portion GR is disposed (e.g., the non-pixel region NPX).

The insulation layers IL2 and IL3 on the side surface of the substrate portion SUB may serve to totally reflect the second light L2 incident into the single photo avalanche diode (SPAD) and proceeding to the non-pixel region NPX. Therefore, it is preferable that the reflectance of the insulation layers IL2 and IL3 with respect to the second light L2 is high.

On the upper surface of the substrate portion SUB, the light receiving pattern LM may be disposed on the insulation layer IL. The light receiving pattern LM may serve to allow the light incident from the outside to be received into each pixel PX1 and PX2. To this end, the light receiving pattern LM may have a convex shape convex upward, and may be formed of a material having a great difference in the refractive index compared to that of the outside air. For example, a refractive index of the light receiving pattern LM may be about 1.5 to about 1.6, but is not limited thereto. As illustrated in FIG. 3, the light receiving pattern LM may be disposed continuously in the pixel region PX and the non-pixel region NPX, and an end of the convex lens shape may be positioned at a center of the pixel region PX, but is not limited thereto. For example, the light receiving pattern LM may be discontinued in the non-pixel region NPX, and in this case, each of the plurality of light receiving patterns (LM) may be disposed in each of the pixel regions (PX).

In some implementations, the single photo avalanche diode SPAD disposed in the pixel region PX may be used as a photoelectric conversion element including a photosensitive p-n junction. For example, the single photo avalanche diode SPAD may detect a single photon (a single photon of L2) reflected by the target object (refer to TO in FIG. 1), and may generate pixel data (or a current pulse, a pixel signal, a pulse signal) corresponding to the detected single photon. At this instance, the pixel data may be generated through a series of processes as the avalanche breakdown is triggered by a single photon incident in a Geiger mode in which a reverse bias voltage higher than a breakdown voltage is applied as a voltage between a cathode and an anode. In the implementations, the non-pixel region NPX is a region without a single photo avalanche diode SPAD and thus does not detect the single photon. In the example in FIG. 3, the non-pixel region NPX is located between two adjacent pixel regions PX and is structured to reflect light from the respective adjacent pixels back to the adjacent pixels to increase the detection by the single photo avalanche diode SPAD of the single photon entering that pixel, thus the overall optical detection efficiency, and, additionally, to reduce undesired optical crosstalk between adjacent pixels that would otherwise adversely reduce the image resolution and quality.

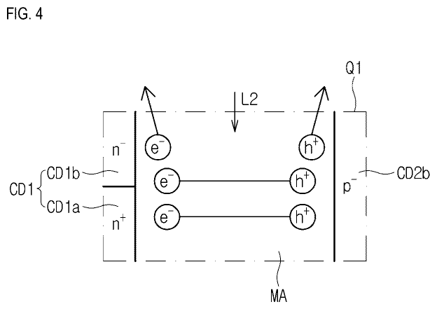

FIG. 4 is an enlarged cross-sectional view of Q1 region of FIG. 3.

Referring to FIG. 4, the avalanche breakdown may occur in the intermediate region MA inside the single photo avalanche diode SPAD. A hole (h+) may be disposed in one region adjacent to the second semiconductor region CD2 of the intermediate region MA, and an electron (e−) may be disposed in another region adjacent to the first semiconductor region CD1 of the intermediate region MA. The hole (h+) in one region and the electron (e−) in another region may form an electron-hole pair to be combined with each other. The electron (e−)-hole (h+) pair may be impact-ionized by a photon of the second light L2.

In more detail, when increasing the electric field by applying the reverse bias voltage to the single photo avalanche diode SPAD, the impact ionization, by which the electron (e−)-hole (h+) pair is generated while the electron (e−) generated attributable to the photon incident due to the strong electric field moves, occurs. As the electron (e−) and the hole (h+) generated due to the impact ionization phenomenon collide with each other, a lot of carriers may be generated.

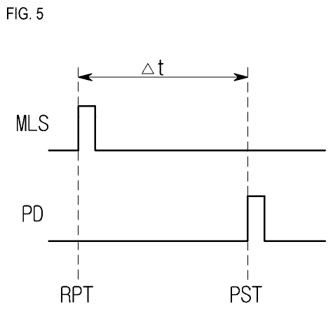

FIG. 5 is a view for describing a direct ToF method of a pixel.

Referring to FIGS. 1 to 5, the light source LS may irradiate the first light L1 (or the irradiation light) to the target object (TO) by a reference pulse signal MLS in a state in which the image sensing device 100 is activated. A time point when a pulse of the reference pulse signal MLS is generated may be defined as a reference pulse time point (RPT). The pixel array 110 and the readout circuit 150 may detect a pulse signal reflected from the target object (TO) and becoming incident and may generate pixel data PD.

The image signal processor 200 may process pixel data PD input from the image sensing device 100, and generate a depth image (in the form of a histogram) indicating a distance to the target object (TO). When the direct ToF method is applied, the image signal processor 200 may calculate a distance to the target object (TO) per pixel based on a time delay indicated by pixel data (PD) received from the readout circuit 150. The image signal processor 200 may analyze the pixel data PD, and may determine a time point when the pixel data PD has a value equal to or greater than threshold data to be a time point of pulse detection PST. The image signal processor 200 may calculate a time of flight Δt (ToF) which is a time gap from the reference pulse time point (RPT) to the time point of pulse detection (PST), and calculate the calculated time of flight Δt and the light velocity (e.g., a value obtained by dividing Δt by 2 is multiplied by the light velocity) so as to calculate a distance between the target object TO and the image sensing device 100.

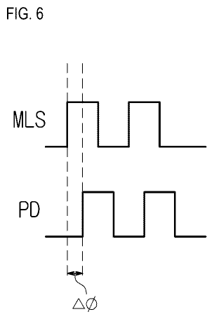

FIG. 6 is a view for describing an indirect ToF method of a pixel.

Referring to FIGS. 1 to 6, the light source LS may irradiate the first light L1 (or the irradiation light) to the target object (TO) by a reference pulse signal MLS in a state in which the image sensing device 100 is activated. A time point when a pulse of the reference pulse signal MLS is generated may be defined as a reference pulse time point (RPT). The pixel array 110 and the readout circuit 150 may detect a pulse signal reflected from the target object (TO) and becoming incident and may generate pixel data PD.

The image signal processor 200 may process pixel data PD input from the image sensing device 100, and generate a depth image (in the form of a histogram) indicating a distance to the target object (TO). When the indirect ToF method is applied, the image signal processor 200 may calculate a distance to the target object (TO) per pixel based on a phase delay Δφ indicated by pixel data (PD) received from the readout circuit 150.

Hereinafter, for convenience of description, the present disclosure will be described centering on the direct ToF method.

FIG. 7 is a view illustrating the imaging system according to an embodiment.

Referring to FIG. 7, the imaging system according to an embodiment may include the single photo avalanche diode SPAD, an analog quenching transistor QX, a readout transistor RT, the readout circuit 150, and an ISP 200. An anode electrode AND may be formed in one end of the single photo avalanche diode SPAD, and a cathode electrode CAT may be formed on another end thereof. The anode electrode AND and the cathode electrode CAT are relative to each other, and positions thereof may be exchanged. For example, the anode electrode AND may be the second semiconductor region CD2 of the single photo avalanche diode SPAD, and the cathode electrode CAT may be the first semiconductor region CD1 of the single photo avalanche diode SPAD, but the embodiments of the present disclosure are not limited thereto. A diode voltage VSPAD may be applied to the anode electrode AND of the single photo avalanche diode SPAD. The cathode electrode CAT may be connected to a first node N1. The second light L2 is applied to the single photo avalanche diode SPAD (refer to FIG. 3). The analog quenching transistor QX is connected to the first node N1. The analog quenching voltage VDD may be applied to a first electrode of the analog quenching transistor QX, a second electrode may be connected to the first node N1, a quenching control signal QCS may be applied to a gate electrode, and turn on/off of the analog quenching transistor QX may be controlled according to the quenching control signal QCS.

A readout transistor RT may be connected to the first node N1. A first electrode of the readout transistor RT may be connected to the first node N1, a second electrode thereof may be connected to the readout circuit 150, a readout control signal RCS may be applied to a gate electrode, and turn on/off of the readout transistor RT may be controlled according to the readout control signal RCS.

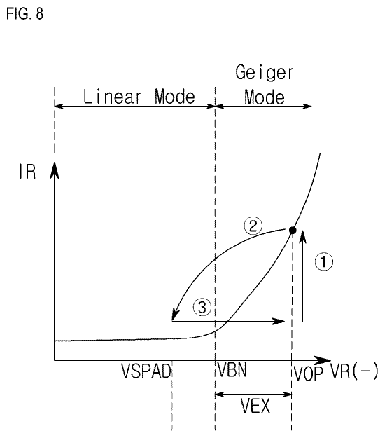

FIG. 8 is a view illustrating a mode of the single photo avalanche diode according to an embodiment. A horizontal axis in FIG. 8 shows a voltage VR applied to the single photo avalanche diode (refer to SPAD in FIG. 7), and a vertical axis therein shows a current IR output from the single photo avalanche diode (refer to SPAD in FIG. 7).

Referring to FIGS. 7 and 8, modes of the single photo avalanche diode may include a Linear mode and a Geiger mode. The Linear mode and the Geiger mode may be divided based on the breakdown voltage VBV. When a voltage applied to the single photo avalanche diode SPAD (hereinafter, referred to as the diode SPAD) is equal to or more than the breakdown voltage VBV, the diode SPAD may operate in the Geiger mode, and when the voltage applied to the single photo avalanche diode SPAD is smaller than the breakdown voltage VBV, the diode SPAD may operate in the Linear mode. The voltage VR applied to the diode SPAD may be based on a negative (−) voltage. Therefore, it is assumed in the present disclosure that the greater the negative (−) value, the greater the magnitude of the voltage. However, the embodiments of the present disclosure are not limited thereto. In the Linear mode and the Geiger mode, the diode voltage VSPAD may have a constant magnitude. For example, the diode voltage VSPAD may be set to have a voltage smaller than the breakdown voltage VBV. When the diode voltage VSPAD is greater than the breakdown voltage VBV, the diode SPAD may enter the Geiger mode, even if the analog quenching transistor QX is not turned on. In this case, even if the light L2 is not applied, the avalanche is generated randomly, and a great current IR may be generated from the diode SPAD. Therefore, the diode voltage VSPAD may be preferably set to have a voltage smaller than the breakdown voltage VBV.

For further description of the Geiger mode and the Linear mode, a magnitude of each voltage will be taken as an example. The breakdown voltage VBV may be −20V, and the diode voltage SPAD may be −19V. When the analog quenching transistor QX is turned off, a voltage applied to the diode SPAD is −19V and is smaller than the breakdown voltage VBV, and the diode SPAD operates in the Linear mode. In the Linear mode, even if the light L2 is incident into the diode SPAD, a magnitude of the current IR output from the diode SPAD may not be great, and the quantity of the carriers may not be many, although the magnitude of the current IR increases in proportion to the quantity of the carriers (e− or h+) generated by the impact ionization. Even if the analog quenching transistor QX is turned on, when the analog quenching voltage VDD is smaller than 1V, the voltage VR applied to the diode SPAD is −19V (a voltage smaller than 1V), which is smaller than the breakdown voltage VBV, and therefore, the diode SPAD operates in the Linear mode.

### Reset Operation

In a reset operation \textcircled{3}, when an analog quenching voltage VDD of 1V is applied, the voltage VR applied to the diode SPAD becomes equal to the breakdown voltage VBV. From this time, the diode SPAD operates in the Geiger mode. In the Geiger mode, as the voltage VR applied to the diode SPAD increases, the magnitude of the current IR output from the diode SPAD dramatically increases. However, in the reset operation \textcircled{3}, when the voltage VR applied to the diode SPAD is set to be equal to the breakdown voltage VBV, the diode SPAD may operate in the Linear mode, rather than the Geiger mode, because of some error. Therefore, in the reset operation \textcircled{3}, the voltage VR applied to the diode SPAD may be set up to an operating voltage VOP. For example, the operating voltage VOP may be greater than the breakdown voltage VBV, and for example, may be assumed to be −23V. That is, an operating voltage VOP greater than the breakdown voltage VBV is preset, and an operation to increase the voltage VR applied to the diode SPAD up to the operating voltage VOP through the analog quenching voltage VDD is performed in the reset operation \textcircled{3}. In order to increase the voltage applied to the diode SPAD to −23V, which is the operating voltage VOP, the analog quenching voltage VDD must be 4V (−19 V−4V=−23V). The voltage obtained by subtracting the breakdown voltage VBV from the operating voltage VOP may be a setting voltage VEX, and in this case, it may be −2V.

### Avalanche Operation

In the avalanche operation \textcircled{1}, the impact ionization occurs for many times in the diode SPAD, and countless carriers are generated, and therefore, the magnitude of the current IR output from the diode SPAD may be great. That is, because the magnitude of the output current IR is great, an operation to generate a pulse signal reflected from the target object TO and becoming incident as described referring to FIG. 4 may be performed in the avalanche operation \textcircled{1} of the diode SPAD. The pulse signal generated from the diode SPAD is provided to the readout circuit 150 when the readout transistor RT is turned on. The TDC 151 of the readout circuit 150 generates the pixel data PD based on the pulse signal generated and provided from the diode SPAD, and the TDC buffer 153 stores the generated pixel data PD.

### Quenching Operation

In the quenching operation \textcircled{2}, the analog quenching transistor QX is turned off, and because of this, the voltage VR applied to the diode SPAD may drop to a level of the diode voltage VSPAD again. The diode SPAD according to an embodiment repeats the reset operation \textcircled{3}, the avalanche operation \textcircled{1}, and the quenching operation \textcircled{2}.

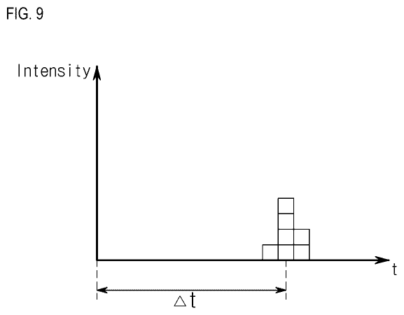

FIG. 9 is a graph which converted pixel data generated by a pixel according to an embodiment into a histogram. The horizontal axis in FIG. 9 shows a time t, and the vertical axis thereof shows an intensity of the signal.

The pixel data PD is generated in the Geiger mode of the diode SPAD described referring to FIG. 7. The ISP (refer to 200 in FIG. 7) may convert the pixel data PD of each diode SPAD into a histogram.

Hereinafter, a method for manufacturing the pixel array described referring to FIG. 3 will be described.

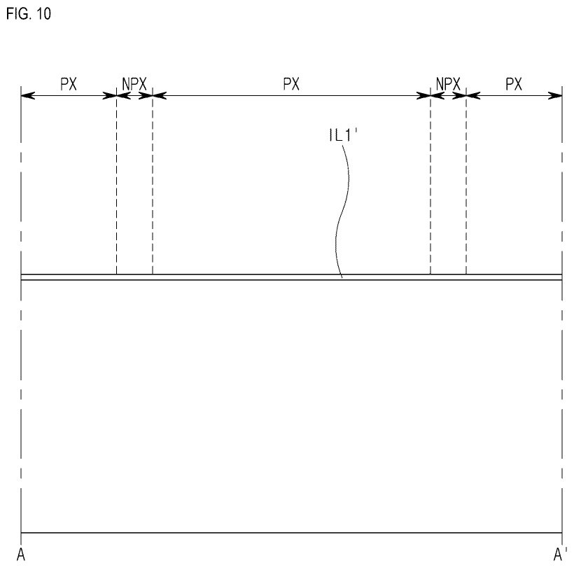

FIGS. 10 to 14 are cross-sectional views during stages of a method for manufacturing the pixel array according to an embodiment. While describing FIGS. 10 to 14, description on components described referring to FIG. 3 will be omitted.

Referring to FIG. 10, a first insulation layer IL1′ is formed on the upper surface of the substrate portion SUB across the pixel region PX and the non-pixel region NPX. The refractive index of the first insulation layer IL1′ may be about 2.2 to 3.1, but the embodiments of the present disclosure are not limited thereto. For example, the first insulation layer IL1′ may include at least one of hafnium oxide (HfO2), titania (TiO2), zinc sulfide (ZnS), aluminum nitride (AlN), gallium phosphide (GaP), or cadmium telluride (CdTE), but the embodiments of the present disclosure are not limited thereto.

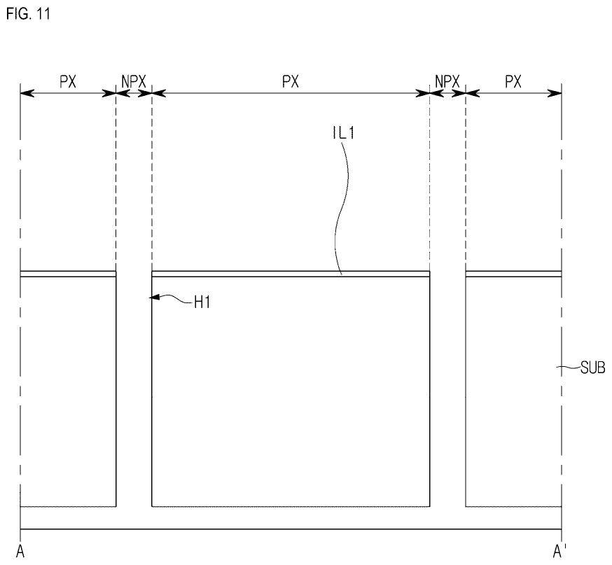

Referring to FIG. 11, the first hole H1 is formed by removing the first insulation layer (refer to IL1′ in FIG. 10) and the substrate portion SUB disposed in the non-pixel region NPX.

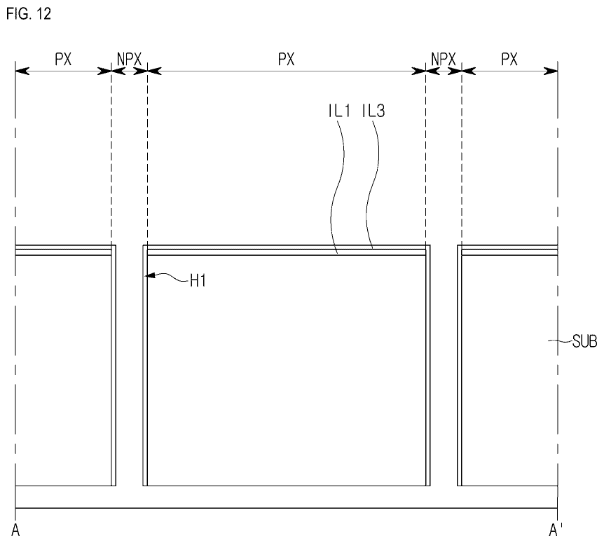

Referring to FIG. 12, the third insulation layer IL3 is formed on the first insulation layer IL1. The third insulation layer IL3 may be formed on the upper surface of the substrate portion SUB, and may be disposed on the first insulation layer IL1. The third insulation layer IL3 may be directly disposed on the first insulation layer IL1. The third insulation layer IL3 may be disposed on the side surface of the substrate portion SUB, and may be in direct contact with the side surface of the substrate portion SUB. The refractive index of the third insulation layer IL3 may be, for example, about 1.5, but the embodiments of the present disclosure are not limited thereto. For example, the third insulation layer IL3 may include aluminum oxide (Al2O3), but the embodiments of the present disclosure are not limited thereto.

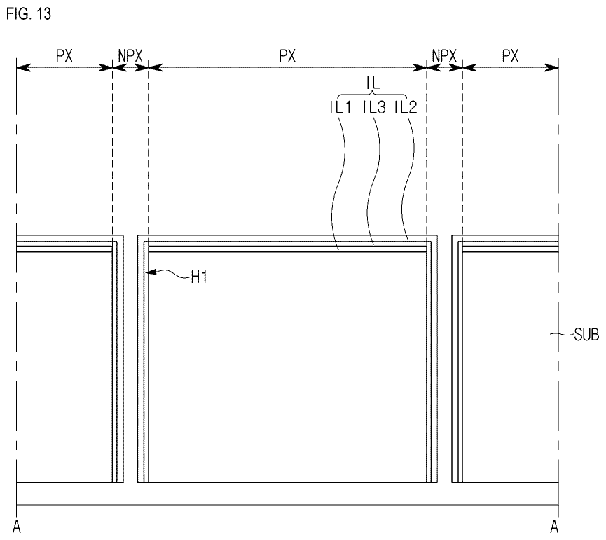

Referring to FIG. 13, the second insulation layer IL2 may be disposed on the third insulation layer IL3. The second insulation layer IL2 may be disposed on the third insulation layer IL3. On the upper surface of the substrate portion SUB, the second insulation layer IL2 may be disposed on the third insulation layer IL3 and may be in direct contact with the third insulation layer IL3. On the side surface of the substrate portion SUB, the second insulation layer IL2 may be in direct contact with the side surface of the third insulation layer IL3. For example, the refractive index of the second insulation layer IL2 may be about 1.4 to 1.5. For example, the second insulation layer IL2 may include silicon dioxide (SiO2), but the embodiments of the present disclosure are not limited thereto.

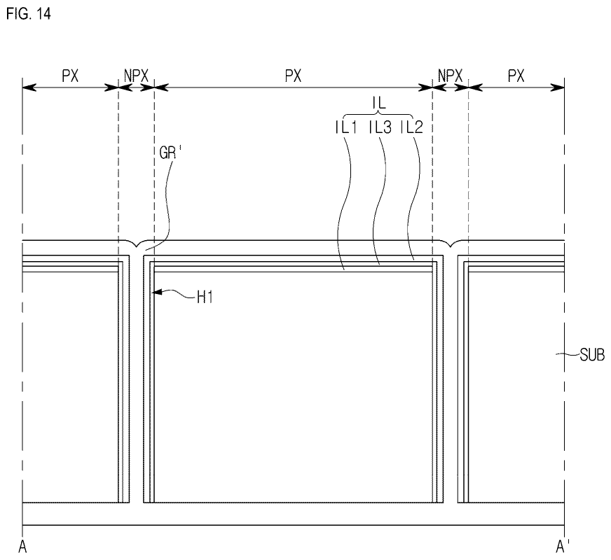

Referring to FIG. 14, a grid portion GR′ may be formed. The grid portion GR′ may be formed across the pixel region PX and the non-pixel region NPX. In the non-pixel region NPX, the grid portion GR′ may be disposed, e.g., in a manner of being sandwiched, between the second insulation layers IL2 respectively disposed in the adjacent pixel regions PX. The grid portion GR′ may be in direct contact with the second insulation layers IL2 respectively disposed in the adjacent pixel regions PX. The grid portion GR′ may include tungsten (W), but embodiments of the present disclosure are not limited thereto. The grid portion GR′ illustrated in FIG. 14 may be etched to be formed as the first grid portion GR1 and the second grid portion GR2 as illustrated in FIG. 3.

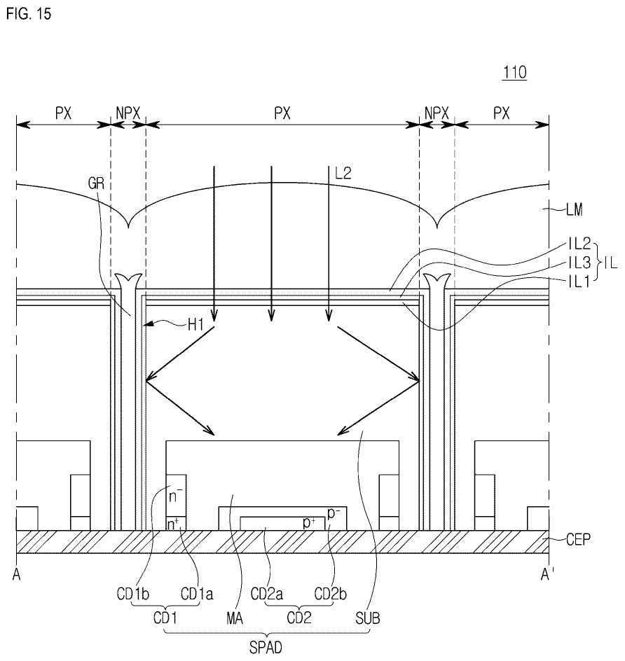

FIG. 15 is a schematic view illustrating light reflection of the pixel array based on some implementations of the disclosed technology.

Referring to FIG. 15, through the light receiving pattern LM, the second light L2 may be incident. The second light L2 which has passed through the light receiving pattern LM may reach the insulation layers IL1, IL2 and IL3. The insulation layers IL1, IL2 and IL3 according to an embodiment may improve reflection with respect to the second light L2, as described above. For example, the refractive index of the second insulation layer IL2 may have a value between the refractive index of the light receiving pattern LM and the refractive index of the first insulation layer IL1, and the refractive index of the first insulation layer IL1 may have a value between the refractive index of the second insulation layer IL2 and the refractive index of the substrate portion SUB. Generally, a reflectance of the light may increase on an interfacial surface between materials, of which a difference between the refractive indexes thereof is great. However, according to the pixel array 110 according to an embodiment, the refractive index of the second insulation layer IL2 has a value between the refractive index of the light receiving pattern LM and the refractive index of the first insulation layer IL1, and the refractive index of the first insulation layer IL1 has a value between the refractive index of the second insulation layer IL2 and the refractive index of the substrate portion SUB, thereby it is possible to increase light transmittance by improving reflection of the second light L2 on the upper surface of the substrate portion SUB. With this configuration, a light absorption rate of the second light L2 with respect to the diode SPAD may increase.

In some implementations, some of the second light L2, which is incident into the substrate portion SUB and proceeds in a downward direction as illustrated in FIG. 15, may change the direction to proceed toward the non-pixel region NPX. When the second light L2 escapes to the non-pixel region NPX, a crosstalk toward an adjacent pixel region PX may occur or the light absorption rate of absorbing the second light L2 of the diode SPAD may decrease.

However, according to the pixel array 110 according to an embodiment, the first insulation layer IL1 may not be disposed on the side surface of the substrate portion SUB, while the second insulation layer IL2 may be in direct contact with the side surface of the substrate portion SUB. As described above, a reflectance of the light may increase on an interfacial surface between materials, of which a difference between the refractive indexes thereof is great. In the pixel array 110 according to an embodiment, the first insulation layer IL1 may not be disposed on the side surface of the substrate portion SUB, because the refractive index of the first insulation layer IL1 is greater than those of the second insulation layer IL2 or the third insulation layer IL3. With this configuration, it is possible to improve the light reflectance by increasing the reflectance of the side surface of the substrate portion SUB.

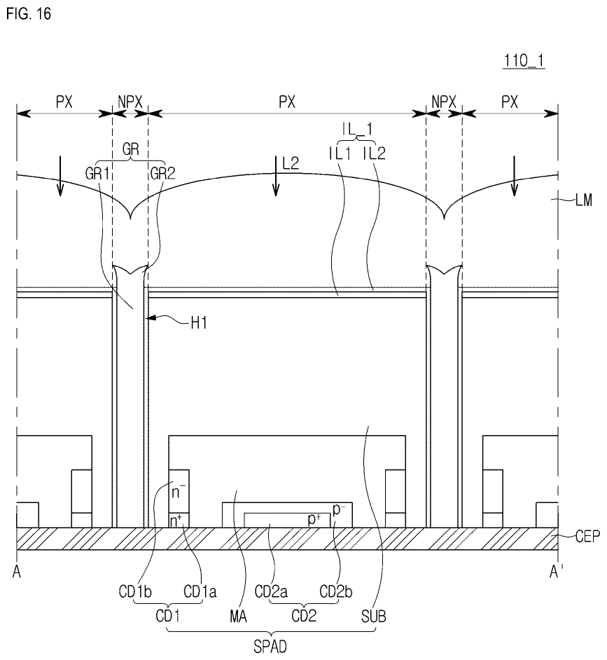

FIG. 16 is a cross-sectional view illustrating the image sensing device according to another embodiment.

Referring to FIG. 16, an insulation layer IL_1 of a pixel array 110_1 of an image sensing device according to the present disclosure is different from the pixel array 110 according to FIG. 3 in that the pixel array 110_1 does not include the third insulation layer IL3.

To describe it in more detail, the first insulation layer IL1 and the second insulation layer IL2 may be sequentially stacked on the upper surface of the substrate portion SUB, and the second insulation layer IL2 and the grid portion GR may be sequentially disposed on the side surface of the substrate portion SUB. The second insulation layer IL2 may be in direct contact with the side surface of the substrate portion SUB.

According to the present disclosure, because the third insulation layer IL3 is omitted on the side surface and the upper surface of the substrate portion SUB, the structure of the pixel array 110_1 may be simplified. In addition, according to FIG. 3, the light receiving pattern LM, the second insulation layer IL2, and the third insulation layer IL3 are disposed in the downward direction on the upper surface of the substrate portion SUB, and because the refractive index of the third insulation layer IL3 is equal to or greater than the refractive index of the second insulation layer IL2, it is likely that the third insulation layer IL3 does not contribute to reduction of the reflectance of the second light L2.

However, according to the present embodiment, there is an effect of simplifying the structure by omitting the third insulation layer IL3.

Since the description on other components have been already provided with reference to FIG. 3, the detailed description thereof will be omitted.

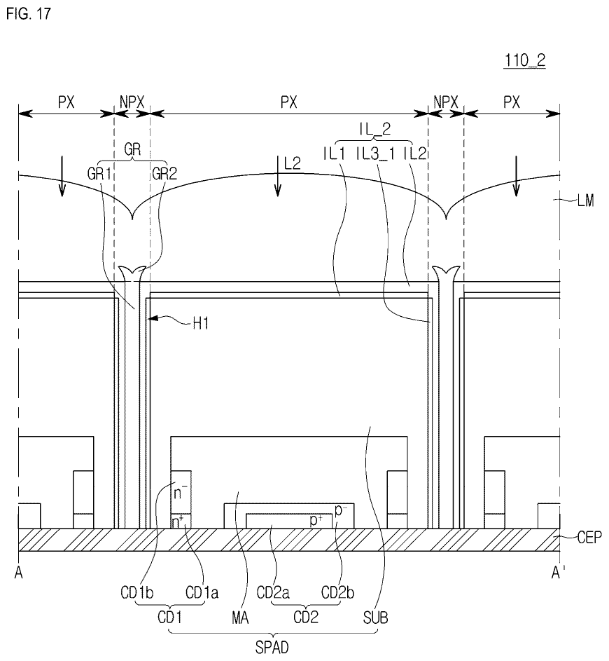

FIG. 17 is a cross-sectional view illustrating an image sensing device according to still another embodiment.

Referring to FIG. 17, a pixel array 110_2 of an image sensing device according to the present embodiment is different from the pixel array 110 according to FIG. 3 in that a third insulation layer IL3_1 is disposed on the side surface of the substrate portion SUB only, and is not disposed on the upper surface of the substrate portion SUB.

In some implementations, a third insulation layer IL3_1 may be in direct contact with the side surface of the substrate portion SUB. In some embodiments, the grid portion GR may be replaced with poly-silicon described in FIG. 3. When the poly-silicon is disposed in the non-pixel region NPX, the hole remaining in the diode SPAD may move to the third insulation layer IL3_1 upon application of the negative voltage to the poly-silicon. Therefore, it is possible to improve a problem that the electrons in the diode SPAD transfer to the non-pixel region NPX.

Since the description on other components have been already described referring to FIG. 3, the detailed description thereof will be omitted.

The image sensing device and the imaging system according to various embodiments of the present disclosure may be described as below.

In one aspect, an image sensing device is provided to comprise: a substrate; a pixel region supported by the substrate and configured to detect incident light from a target object to generate pixel data; a non-pixel region disposed on a side of the pixel region; insulation material disposed on a side surface and an upper surface of the substrate; a grid structure disposed on a side surface of the insulation material; and a light receiving pattern disposed on the insulation material and configured to collect the incident light from the target object and to direct the incident light into the pixel region to be detected, wherein a thickness of the insulation material on the upper surface of the substrate is greater than a thickness of the insulation material on the side surface of the substrate.

In some implementations, the insulation material further comprises: a first insulation layer on the upper surface of the substrate, and a second insulation layer on the first insulation layer.

In some implementations, a refractive index of the first insulation layer is greater than a refractive index of the second insulation layer and smaller than a refractive index of the substrate.

In some implementations, the second insulation layer is further disposed to be in direct contact with a side surface of the first insulation layer.

In some implementations, the grid structure is in direct contact with the insulation material.

In some implementations, the grid structure includes a first grid portion having a surface height equal to a surface height of the insulation material, and a second grid portion protruding from the first grid portion.

In some implementations, the first grid portion and the second grid portion include a same material.

In another aspect, an image sensing device is provided to comprise: a substrate including a pixel region and a non-pixel region around the pixel region, and a hole recessing in the non-pixel region, the pixel region including a photoelectric conversion element configured to generate pixel data in response to a detection of light from a target object and the non-pixel region configured without including the photoelectric conversion element; a first insulation layer on an upper surface of the substrate; a second insulation layer on the first insulation layer; a grid structure on a side surface of the second insulation layer; and a light receiving pattern on the second insulation layer, wherein the second insulation layer is in direct contact with a side surface of the substrate.

In some implementations, a refractive index of the first insulation layer is greater than a refractive index of the second insulation layer and smaller than a refractive index of the substrate.

In some implementations, the second insulation layer is in direct contact with a side surface of the first insulation layer.

In some implementations, the grid structure is in direct contact with the second insulation layer.

In some implementations, the grid structure includes a first grid structure having a surface with a height equal to a height of a surface of the second insulation layer, and a second grid structure protruding from the first grid structure.

In some implementations, the first grid structure and the second grid structure include a same material.

In some implementations, a refractive index of the first insulation layer is in a range between 2.2 and 3.1.

In some implementations, the first insulation layer includes at least one of hafnium oxide (HfO2), titania (TiO2), zinc sulfide (ZnS), aluminum nitride (AlN), gallium phosphide (GaP), or cadmium telluride (CdTE).

In some implementations, the second insulation layer includes silicon dioxide (SiO2).

In some implementations, the image sensing device further comprises: a third insulation layer on the second insulation layer, wherein the third insulation layer is in direct contact with the grid structure.

In another aspect, an image sensing device is provided to comprise: a substrate including a pixel region, a non-pixel region around the pixel region, and a hole recessing the substrate in the non-pixel region; a first insulation layer on an upper surface of the substrate; a second insulation layer on the first insulation layer; and a third insulation layer between the first insulation layer and the second insulation layer, wherein a refractive index of the first insulation layer has a value between a refractive index of the second insulation layer and a refractive index of the substrate, and wherein a refractive index of the second insulation layer is lower than or equal to a refractive index of the third insulation layer.

In some implementations, on the upper surface of the substrate, the second insulation layer is in direct contact with the first insulation layer.

In some implementations, the first insulation layer includes at least one of hafnium oxide (HfO2), titania (TiO2), zinc sulfide (ZnS), aluminum nitride (AlN), gallium phosphide (GaP), or cadmium telluride (CdTE), the second insulation layer includes silicon dioxide (SiO2), and the third insulation layer includes aluminum oxide (Al2O3).

While various embodiments have been described with reference to the exemplified drawings, variations and improvements of the disclosed embodiments and other embodiments may be made based on what is described or illustrated in this document.

What is claimed is:

1. An image sensing device, comprising:
a substrate;
a pixel region supported by the substrate and configured to detect incident light from a target object to generate pixel data;
a non-pixel region disposed on a side of the pixel region;
insulation material disposed on a side surface and an upper surface of the substrate;
a grid structure disposed on a side surface of the insulation material; and
a light receiving pattern disposed on the insulation material and configured to collect the incident light from the target object and to direct the incident light into the pixel region to be detected, wherein a thickness of the insulation material on the upper surface of the substrate is greater than a thickness of the insulation material on the side surface of the substrate.

2. The image sensing device of claim 1, wherein the insulation material further comprises:
a first insulation layer on the upper surface of the substrate, and
a second insulation layer on the first insulation layer.

3. The image sensing device of claim 2,
wherein a refractive index of the first insulation layer is greater than a refractive index of the second insulation layer and smaller than a refractive index of the substrate.

4. The image sensing device of claim 2,
wherein the second insulation layer is further disposed to be in direct contact with a side surface of the first insulation layer.

5. The image sensing device of claim 1,
wherein the grid structure is in direct contact with the insulation material.

6. The image sensing device of claim 5,
wherein the grid structure includes a first grid portion having a surface height equal to a surface height of the insulation material, and a second grid portion protruding from the first grid portion.

7. The image sensing device of claim 6,
wherein the first grid portion and the second grid portion include a same material.

8. An image sensing device, comprising:
a substrate including a pixel region and a non-pixel region around the pixel region, and a hole recessing in the non-pixel region, the pixel region including a photoelectric conversion element configured to generate pixel data in response
to a detection of light from a target object and the non-pixel region configured without including the photoelectric conversion element;
a first insulation layer on an upper surface of the substrate;
a second insulation layer on the first insulation layer;
a grid structure on a side surface of the second insulation layer; and
a light receiving pattern on the second insulation layer,
wherein the second insulation layer is in direct contact with a side surface of the substrate.

9. The image sensing device of claim 8,
wherein a refractive index of the first insulation layer is greater than a refractive index of the second insulation layer and smaller than a refractive index of the substrate.

10. The image sensing device of claim 8,
wherein the second insulation layer is in direct contact with a side surface of the first insulation layer.

11. The image sensing device of claim 8,
wherein the grid structure is in direct contact with the second insulation layer.

12. The image sensing device of claim 8,
wherein the grid structure includes a first grid structure having a surface with a height equal to a height of a surface of the second insulation layer, and a second grid structure protruding from the first grid structure.

13. The image sensing device of claim 12,
wherein the first grid structure and the second grid structure include a same material.

14. The image sensing device of claim 8,
wherein a refractive index of the first insulation layer is in a range between 2.2 and 3.1.

15. The image sensing device of claim 8,
wherein the first insulation layer includes at least one of hafnium oxide (HfO2), titania (TiO2), zinc sulfide (ZnS), aluminum nitride (AlN), gallium phosphide (GaP), or cadmium telluride (CdTE).

16. The image sensing device of claim 8,
wherein the second insulation layer includes silicon dioxide (SiO2).

17. The image sensing device of claim 8, further comprising:
a third insulation layer on the second insulation layer,
wherein the third insulation layer is in direct contact with the grid structure.

18. An image sensing device, comprising:
a substrate including a pixel region, a non-pixel region around the pixel region, and a hole recessing the substrate in the non-pixel region;
a first insulation layer on an upper surface of the substrate;
a second insulation layer on the first insulation layer; and
a third insulation layer between the first insulation layer and the second insulation layer,
wherein a refractive index of the first insulation layer has a value between a refractive index of the second insulation layer and a refractive index of the substrate, and
wherein a refractive index of the second insulation layer is lower than or equal to a refractive index of the third insulation layer.

19. The image sensing device of claim 18,
wherein on the upper surface of the substrate, the second insulation layer is in direct
contact with the first insulation layer.

20. The image sensing device of claim 18,
wherein the first insulation layer includes at least one of hafnium oxide (HfO2), titania
(TiO2), zinc sulfide (ZnS), aluminum nitride (AlN), gallium phosphide (GaP), or cadmium telluride (CdTE), the second insulation layer includes silicon dioxide (SiO2), and the third insulation layer includes aluminum oxide (Al2O3).
